(19) United States
(12) Patent Application Publication
(10) Pub. No.: US 2016/0020423 A1
(43) Pub. Date: Jan. 21, 2016

(54) RESIN COMPOSITION FOR ELEMENT ENCAPSULATION FOR ORGANIC ELECTRONIC DEVICES, RESIN SHEET FOR ELEMENT ENCAPSULATION FOR ORGANIC ELECTRONIC DEVICES, ORGANIC ELECTROLUMINESCENT ELEMENT, AND IMAGE DISPLAY DEVICE

(71) Applicant: FURUKAWA ELECTRIC CO., LTD., Tokyo (JP)

(72) Inventors: Keiji SAITO, Tokyo (JP); Masami AOYAMA, Tokyo (JP); Kunihiko ISHIGURO, Tokyo (JP); Naoaki MIHARA, Tokyo (JP); Tetsuya MIEDA, Tokyo (JP)

(73) Assignee: FURUKAWA ELECTRIC CO., LTD., Tokyo (JP)

(21) Appl. No.: 14/868,001

(22) Filed: Sep. 28, 2015

Related U.S. Application Data
(63) Continuation of application No. PCT/JP2014/056199, filed on Mar. 10, 2014.

(30) Foreign Application Priority Data
Mar. 29, 2013 (JP) 2013-074750

(51) Int. Cl. H01L 51/52; H01L 27/32; H01L 51/00

(52) U.S. Cl. CPC H01L 51/5246; H01L 51/004; H01L 51/0077; H01L 51/0036; H01L 51/5259; H01L 27/3241

(57) ABSTRACT

Provided are a resin composition for element encapsulation for organic electronic devices and other things, which have excellent long-term reliability and excellent visibility by capturing not only the moisture on the front surface or lateral surfaces of the resin composition for element encapsulation for organic electronic devices, but also the moisture permeating through the interior of the resin composition for element encapsulation for organic electronic devices. The resin composition includes a polyisobutylene resin (A) containing a polyisobutylene skeleton in a main chain or in a side chain and having a weight average molecular weight (Mw) of 300,000 or more; and a tackifying agent (B) as main components, includes an organometallic compound (C) having hygroscopic properties, and has a water content of 1000 ppm or less.

### TECHNICAL FIELD

The present invention relates to a resin composition for element encapsulation for organic electronic devices, which is intended to protect an element for organic electronic devices from oxygen or moisture, a resin sheet for element encapsulation for organic electronic devices, and an element for organic electronic devices and an image display device that are encapsulated with the resin composition for element encapsulation for organic electronic devices.

### BACKGROUND ART

In recent years, research on various organic electronic devices such as organic electroluminescent (hereinafter, also referred to as “organic EL”) displays, organic EL lightings, organic semiconductors and organic solar cells has been actively conducted. Particularly, since organic EL displays are characterized by high precision and a high field of view, the organic EL displays are expected as the next-generation displays that will substitute liquid crystal displays, and the range of applications of the organic EL displays is extending widely from the field of lightings such as backlights for displays and all-night lights, to the field of flat displays such as tablet type terminal displays and television screen displays.

An organic EL element is configured to include an organic compound layer including a light emitting layer, and a pair of electrodes sandwiching this organic compound layer. Specifically, it is known that an organic EL element is basically composed of anode/organic light emitting layer/cathode, and a hole injection layer or an electron injection layer is appropriately provided to this configuration. Furthermore, such an organic EL element has properties such as low voltage driving, high efficiency, and high luminance, and since such an organic EL element is a self-luminescent device, light can be extracted from either side of the anode layer and the cathode layer. Therefore, a top emission mode and a bottom emission mode are available as the light emission mode of organic EL devices.

On the other hand, organic EL elements are susceptible to the influence of moisture, oxygen and the like, and when an organic EL element is driven in air, the luminescence characteristics are rapidly deteriorated so that non-light emitting areas (dark spots) are generated due to infiltration of moisture. Generation of these dark spots leads to serious defects in the light sources of displays and the like. Thus, it is necessary to maintain air-tightness of organic EL elements so as to prevent infiltration of moisture, oxygen and the like to the organic EL layer, and to promote longevity of luminance, which is a characteristic of organic EL elements.

Therefore, development of a method of coating an organic EL element with a sealing film formed by a moisture-proof polymer film and an adhesive layer (see, for example, Patent Document 1), or a sealing film containing a polyisobutylene resin as a main component (see, for example, Patent Document 2 and Patent Document 3) has been achieved.

Furthermore, attempts have been made to promote water permeability reduction of adhesive films using less water-permeable resins, and to further promote water permeability reduction by dispersing a moisture trapping agent, a so-called getter agent, in the resin. For example, there is an example of adding a metal alkoxide to a resin composition prepared by mixing a long-chain hydrocarbon-based polymer and a carboxyl group-terminal silicone oil (see, for example, Patent Document 4), or an example of adding organified clay to polyisobutylene (see, for example, Patent Document 5).

### CITATION LIST

### Patent Document

Patent Document 1: JP 05-101884 A
Patent Document 2: JP 2009-524705 A
Patent Document 3: JP 2007-057523 A
Patent Document 4: JP 2012-38660 A
Patent Document 5: JP 2012-193335 A

### DISCLOSURE OF THE INVENTION

### Problem to be Solved by the Invention

However, in the inventions described in Patent Documents 1 to 3, there have been occasions in which the water included in the sealing layer itself affects the elements. Furthermore, when an organic EL element is encapsulated with an element substrate and a sealing substrate formed from glass or the like, with a sealing layer interposed therebetween, the encapsulation has been insufficient to suppress moisture infiltration through the end surfaces (lateral surfaces) of the sealing layer, where the sealing layer is not brought into contact with the element substrate and the sealing substrate. Furthermore, in the invention described in Patent Document 4, there has been a problem that the metal alkoxide undergoes a gelling reaction with the carboxyl groups and significantly affects manufacturability, and in the invention described in Patent Document 5, there has been a problem that visibility (light transmittance) decreases to a large extent because of the difference between the refractive indices of the organified clay, which is an inorganic material, and the resin. Furthermore, in Patent Document 2, water permeability reduction has been attempted by providing a trapping layer for metal oxides or organometallic compounds; however, since the trapping layer and the sealing layer do not form the same layer and have different configurations, the effect of removing the moisture that passes through the interior of the sealing layer is low.

Thus, an object of the present invention is to provide a resin composition for element encapsulation for organic electronic devices, which exhibits excellent long-term reliability by capturing not only the moisture on the front surface or lateral surfaces of the resin composition for element encapsulation for organic electronic devices, but also the moisture permeating through the interior of the resin composition for element encapsulation for organic electronic devices, and which exhibits excellent visibility; a resin sheet for element encapsulation for organic electronic devices; and an element for organic electronic devices and an image display device, which are encapsulated with the resin composition for element encapsulation for organic electronic devices.

### Means for Solving Problem

In order to solve the problems described above, the resin composition for element encapsulation for organic electronic devices according to the present invention includes a polyisobutylene resin (A) that contains a polyisobutylene skeleton in a main chain or in a side chain and has a weight average molecular weight (Mw) of 300,000 or more; and a tackifying agent (B) as main components, further includes an organometallic compound (C) having hygroscopic properties, and has a water content of 1000 ppm or less.

It is preferable that in regard to the resin composition for element encapsulation for organic electronic devices, the moisture permeability of the resin composition is less than 100 μm·g/m²·day.

Furthermore, it is preferable that the resin composition for element encapsulation for organic electronic devices includes the tackifying agent (B) in an amount of 10% to 80% by mass relative to the total amount.

Furthermore, it is preferable that in regard to the resin composition for element encapsulation for organic electronic devices, the tackifying agent (B) is one kind or two or more kinds of hydrogenated resins selected from the group consisting of hydrides of petroleum resins, hydrogenated rosin, and hydrogenated terpene resins.

Furthermore, it is preferable that in regard to the resin composition for element encapsulation for organic electronic devices, the amount of extrusion, which is the difference between the maximum length of one edge in a state that the resin composition is encapsulated between two sheets of glass plates, and the maximum length of one edge after leaving the resin composition in a state of being encapsulated between two sheets of glass plates, to stand for 150 hours under the conditions of a temperature of 85° C. and a relative humidity of 85%, is less than 2 mm.

Furthermore, it is preferable that the organometallic compound (C) is incorporated such that the content of the metal is 0.05% to 2.0% by mass relative to the total amount.

Furthermore, it is preferable that the organometallic compound (C) is represented by the following Formula (1):

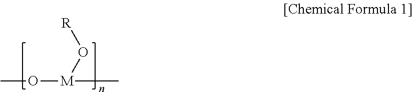

wherein R represents a hydrogen atom, or any one of organic functional groups having 8 or fewer carbon atoms which may have a substituent including an alkyl group, an aryl group, an alkenyl group, an alkoxy group, a cycloalkyl group, a heterocyclic group, and an acyl group; M represents a divalent to tetravalent metal atom; n represents the degree of polymerization and is an integer of 1 or more; and R's may be respectively identical organic functional groups or may be different organic groups.

Furthermore, it is preferable that in regard to the resin composition for element encapsulation for organic electronic devices, the organometallic compound (C) is an organometal having a ligand selected from the group consisting of an alcohol, a diketone, a β-keto ester, and an ether.

Furthermore, it is preferable that in regard to the resin composition for element encapsulation for organic electronic devices, the light transmittance in a wavelength region of 550 nm is 85% or higher.

Furthermore, in order to solve the problems described above, the resin sheet for element encapsulation for organic electronic devices according to the present invention has at least a sealing layer formed by the resin composition for element encapsulation for organic electronic devices according to any one of the above-described items.

Furthermore, it is preferable that the resin sheet for element encapsulation for organic electronic devices is provided with a sealing substrate for encapsulating an element for organic electronic devices together with the sealing layer, on the surface of the sealing layer opposite to the surface that is pasted to the element for organic electronic devices.

Furthermore, it is preferable that the resin sheet for element encapsulation for organic electronic devices has a thickness of the sealing layer of 1 to 50 μm.

Furthermore, the organic electroluminescent element according to the present invention is encapsulated with the resin composition for element encapsulation for organic electronic devices of any one of the above-described items. Furthermore, the organic electroluminescent element according to the present invention is encapsulated using the sealing layer of the resin sheet for element encapsulation for organic electronic devices according to any one of the above-described items.

Furthermore, the image display device according to the present invention includes the organic electroluminescent element.

### Effect of the Invention

Since the transparent resin composition for organic EL element encapsulation and the resin sheet for element encapsulation for organic electronic devices according to the present invention contain organometallic compounds, even the moisture that penetrates through lateral surfaces of the resin composition for element encapsulation for organic electronic devices and permeates through the interior of the resin composition for element encapsulation for organic electronic devices, is captured by these organometallic compounds, and thereby generation of dark spots can be suppressed. Therefore, a transparent resin composition for organic EL element encapsulation and a resin sheet for element encapsulation for organic electronic devices, which have excellent long-term reliability, can be provided. Furthermore, since an organometallic compound is incorporated, excellent visibility is obtained. Therefore, the transparent resin composition for organic EL element encapsulation and the resin sheet for element encapsulation for organic electronic devices are not only applicable to bottom emission type organic EL devices, but also particularly useful for top emission type organic EL devices.

Furthermore, the organic electroluminescent element and the image display device according to the present invention are encapsulated by the transparent resin composition for organic EL element encapsulation according to the present invention, and since the organometallic compound included in the resin composition for element encapsulation for organic electronic devices captures the moisture that penetrates through lateral sides of the resin composition for element encapsulation for organic electronic devices and permeate through the interior of the resin composition for element encapsulation for organic electronic devices, generation of dark spots is suppressed, improved visibility of images can be obtained, and excellent long-term reliability is also obtained.

### BRIEF DESCRIPTION OF DRAWINGS

FIG. 1 is a cross-sectional diagram schematically illustrating the structure of the resin sheet for element encapsulation for organic electronic devices related to an embodiment of the present invention;

FIG. 2 is a cross-sectional diagram schematically illustrating the structure of an image display device which uses the resin sheet for element encapsulation for organic electronic devices related to the embodiment of the present invention; and

FIGS. 3A-3D are explanatory diagrams for schematically explaining an application example of the resin sheet for element encapsulation for organic electronic devices related to the embodiment of the present invention.

### MODE(S) FOR CARRYING OUT THE INVENTION

Hereinafter, an embodiment of the present invention will be explained in detail.

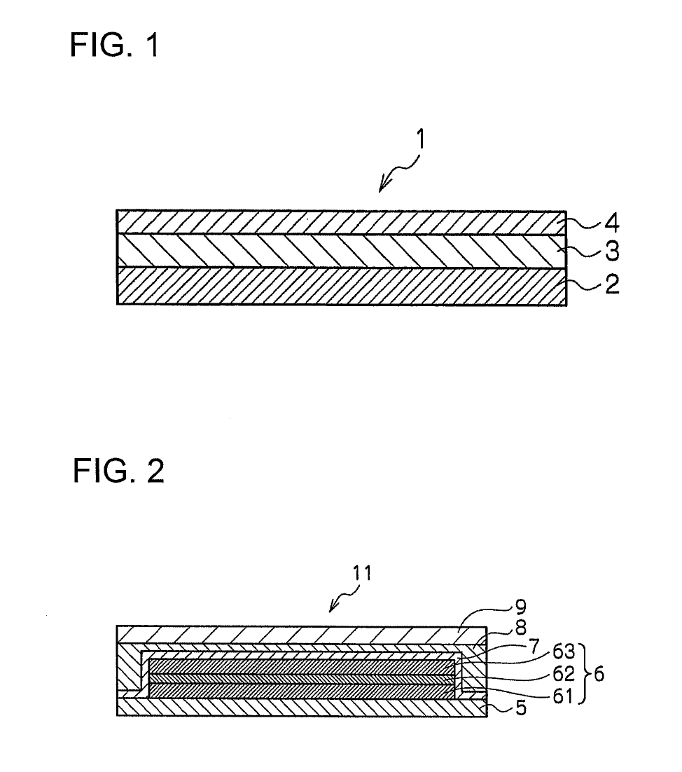

The resin sheet for element encapsulation for organic electronic devices 1 related to the embodiment of the present invention has at least one sealing layer 3 formed on at least any side of a substrate sheet 2. FIG. 1 is a schematic cross-sectional diagram illustrating a preferred embodiment of the resin sheet for element encapsulation for organic electronic devices 1 of the present invention. As illustrated in FIG. 1, the resin sheet for element encapsulation for organic electronic devices 1 includes a substrate sheet 2, and a sealing layer 3 is formed on the substrate sheet 2. Also, the resin sheet for element encapsulation for organic electronic devices 1 further includes a release film 4 for protecting the sealing layer 3, on the sealing layer 3.

Hereinafter, various constituent elements of the resin sheet for element encapsulation for organic electronic devices 1 of the present embodiment will be explained in detail.

(Substrate Sheet 2 and Release Film 4)

The substrate sheet 2 is intended to temporarily fix the resin composition for the purpose of improving handleability when the resin composition that constitutes the sealing layer 3 is made into a film form. Furthermore, the release film 4 is used for the purpose of protecting the sealing layer 3.

The substrate sheet 2 and the release film 4 are not particularly limited, and examples thereof include a polyethylene film, a polypropylene film, a polybutene film, a polybutadiene film, a polymethylpentene film, a polyvinyl chloride film, a vinyl chloride copolymer film, a polyethylene terephthalate film, a polyethylene naphthalate film, a polybutylene terephthalate film, a polyurethane film, an ethylene-vinyl acetate copolymer film, an ionomer resin film, an ethylene-(meth)acrylic acid copolymer film, an ethylene-(meth)acrylic ester copolymer film, a polystyrene film, a polycarbonate film, a polyimide film, and a fluororesin film. Furthermore, crosslinked films of these films are also used. Also, a release paper obtained by coating such a film on one surface of or on both surfaces of base paper, may also be used. Moreover, laminate films of these films may also be used. Particularly, in view of cost, handleability and the like, it is preferable to use polyethylene terephthalate.

Regarding the peeling force when the sealing layer 3 is peeled off from the substrate sheet 2 and the release film 4, for example, the peeling force is preferably 0.3 N/20 mm or less, and more preferably 0.2 N/20 mm. There are no particular limitations on the lower limit of the peeling force, but a peeling force of 0.005 N/20 mm or more is practical. Furthermore, in order to improve handleability, it is preferable to use materials having peeling force different from that of the sealing layer 3 in the substrate sheet 2 and the release film 4.

The film thicknesses of the substrate sheet 2 and the release film are usually 5 to 300 μm, preferably 10 to 200 μm, and particularly preferably about 20 to 100 μm.

(Sealing Layer 3)

The resin composition for element encapsulation for organic electronic devices according to the present invention that constitutes a sealing layer 3 includes a polyisobutylene resin (A) containing a polyisobutylene skeleton in a main chain or in a side chain and having a weight average molecular weight (Mw) of 300,000 or more, and a tackifying agent (B), as main components, also includes an organometallic compound (C) having hygroscopic properties, and has a water content of 1000 ppm or less.

[Polyisobutylene Resin (A)]

Regarding the polyisobutylene resin (A), any polyisobutylene resin containing a polyisobutylene skeleton in the main chain or in a side chain and having a weight average molecular weight (Mw) of 300,000 or more can be used without any particular limitations. The polyisobutylene resin is formed from a copolymer of an isobutylene monomer and one or more kinds of olefins, preferably conjugated olefins, as co-monomers. The polyisobutylene resin is usually produced by a slurry method of using methyl chloride as a medium, and using a Friedel-Crafts catalyst as a part of the polymerization initiator. Such a polyisobutylene resin is characterized by its high water vapor barrier properties and high tacky adhesiveness.

If the polyisobutylene resin (A) has a mass average molecular weight (Mw) of less than 300,000, a desired moisture permeability cannot be achieved, fluidity of the resin composition at a high temperature increases, the amount of extrusion is increased, and therefore, there is a possibility that the increased amount of extrusion may lead to contamination of electronic components around a sealed element for organic electronic devices.

Examples of the polyisobutylene resin (A) include OPPANOL B50, OPPANOL B80, OPPANOL B100, and OPPANOL B150, all manufactured by BASF SE. These may be used singly, or two or more kinds thereof may be used in combination after an adjustment of the viscosity.

[Tackifying Resin (B)]

A tackifying resin is used for the purpose of imparting appropriate viscosity and adhesiveness. Examples of the tackifying resin include rosin, rosin derivatives (hydrogenated rosin, disproportionated rosin, polymerized rosin, rosin esters (such as a rosin esterified with alcohol, glycerin, pentaerythritol etc.)), terpene resins (α-pinene and β-pinene), terpene-phenol resins, aromatic modified terpene resins, hydrogenated terpene resins, C5-based petroleum resins, C9-based petroleum resins, petroleum resins obtainable by copolymerizing C5-based petroleum resins and C9-based petroleum resins, DCPD type petroleum resins, hydrides of C5-based petroleum resins, hydrides of C9-based petroleum resins, hydrides of petroleum resins obtainable by copolymerizing C5-based petroleum resins and C9-based petroleum resins, hydrides of DCPD type petroleum resins, coumarone-indene resins, styrene-based resins, phenolic resins, xylene resins, and polybutene.

Among them, one kind or two or more kinds of hydrogenated resins selected from the group consisting of hydrides of various petroleum resins, hydrogenated rosin-based resins, and hydrogenated terpene-based resins are suitably used from the viewpoint of having satisfactory compatibility with the polyisobutylene resin (A) and being capable of forming a resin composition with excellent transparency. Among these, a hydride of a C5-based petroleum resin, a hydride of a C9-based petroleum resin, and a hydride of a petroleum resin obtainable by copolymerizing a C5-based petroleum resin and a C9-based petroleum resin are suitably used from the viewpoint of having satisfactory water vapor barrier capacity.

The softening points of the hydrides of petroleum resins described above are preferably 60° C. to 150° C. If the softening point is below 60° C., since the cohesive force of the composition decreases, the retention characteristics at high temperatures are deteriorated, and therefore, the amount of extrusion may be increased. If the softening point is higher than 150° C., sealability may decrease because fluidity of the composition decreases.

The hydride of the petroleum resin is commercially available from, for example, Arakawa Chemical Industries, Ltd. and Idemitsu Kosan Co., Ltd.

The amount of incorporation of the tackifying agent (B) may be any arbitrary amount; however, it is preferable that the tackifying agent is included in an amount of 10% to 80% by mass relative to the total amount of the resin composition for element encapsulation for organic electronic devices. The amount of incorporation is more preferably in the range of 30% to 80% by mass, and even more preferably in the range of 40% to 65% by mass. If the amount of incorporation is less than 10% by mass, the resin composition cannot sufficiently exhibit the functions of imparting viscosity and adhesiveness, and sealability decreases. If the amount of incorporation is more than 80% by mass, sealability may decrease because fluidity of the composition decreases.

[Organometallic Compound (C)]

The organometallic compound (C) is added for the purpose of capturing the trace amount of moisture present in the system of the resin composition; the moisture that penetrates through the front surface or lateral surfaces of a sealing layer 3 or a transparent resin layer for organic EL element encapsulation 8 and permeates through the interior of the layer, during the process of forming the sealing layer 3 or the transparent resin layer for organic EL element encapsulation 8 (sealing layer 3 in an encapsulated state, see FIG. 2); and the moisture that penetrates through the lateral surfaces of the sealing layer 3 or the transparent resin layer for organic EL element encapsulation 8 and permeates through the interior of the layer, after the sealing layer 3 or the transparent resin layer for organic EL element encapsulation 8 has been formed. When the organometallic compound (C) is added, deterioration of the organic EL element 6 (see FIG. 2) caused by moisture is suppressed, and a resin sheet for element encapsulation for organic electronic devices 1 having excellent long-term reliability can be provided. Furthermore, since the compound is an organometallic compound, the decrease in transparency or visibility can be reduced.

It is preferable that the organometallic compound (C) is represented by the following formula (1):

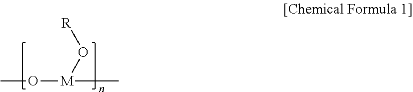

wherein R represents a hydrogen atom, or any one of organic functional groups having 8 or fewer carbon atoms which may have a substituent including an alkyl group, an aryl group, an alkenyl group, an alkoxy group, a cycloalkyl group, a heterocyclic group, and an acyl group; M represents a divalent to tetravalent metal atom; n represents the degree of polymerization, and is an integer of 1 or larger; and R's may be respectively identical organic functional groups or may be different organic functional groups.

Furthermore, the organometallic compound (C) is preferably an organometallic complex, and particularly, an organometallic complex having a ligand selected from the group consisting of an alcohol, a diketone, a β-keto ester, and an ether, and having at least one alkyl acetoacetate group, is preferred. When such an organometallic complex is used, the organometallic complex exhibits satisfactory compatibility with polyisobutylene or a petroleum resin.

Among them, an aluminum alkyl acetoacetate having 1 to 8 carbon atoms is suitably used from the viewpoint that since the aluminum alkyl acetoacetate has high compatibility with the polyisobutylene resin (A) in particular, a resin composition having excellent transparency can be formed.

The aluminum alkyl acetoacetate having 1 to 8 carbon atoms is commercially available from, for example, Kawaken Fine Chemicals Co., Ltd. and Hope Chemical Co., Ltd. Furthermore, these organometallic complexes can be used singly or in combination of two or more kinds thereof.

In regard to the amount of incorporation of the organometallic compound (C), the organometallic compound (C) is preferably incorporated such that the content of the metal is 0.05% to 2.0% by mass, and more preferably 0.5% to 2.0% by mass, relative to the total amount of the resin composition for element encapsulation for organic electronic devices. With an amount of incorporation which gives a metal content of less than 0.05% by mass, moisture may not be sufficiently captured. On the other hand, with an amount of incorporation of more than 2.0% by mass, the function of the tackifying agent is inhibited, and sealability may decrease.

[Plasticizer]

The transparent resin composition for organic EL element encapsulation may include a plasticizer. Fluidity can be modified by introducing a plasticizer. Examples of the plasticizer include waxes, paraffin, phthalic acid esters, adipic acid esters, and polybutene. Among them, a polybutene having an isobutylene skeleton is preferred because this polybutene has a high effect of decreasing the viscosity and has satisfactory compatibility with the polyisobutylene resin (A).

The number average molecular weight of the plasticizer is preferably from 300 to 50,000, more preferably from 300 to 10,000, and even more preferably from 300 to 3,000. If the number average molecular weight is less than 300, the plasticizer may migrate to the element for organic electronic devices, and dark spots may be generated. If the number average molecular weight is more than 50,000, the effect of decreasing the viscosity is reduced. The molecular weight of the plasticizer can be controlled, for example, in the case of polybutene, by regulating the amount of addition of aluminum chloride or the reaction temperature in a production method of using aluminum chloride as a polymerization catalyst.

The amount of incorporation of the plasticizer is preferably 5% to 30% by mass, and more preferably 5% to 20% by mass, relative to the total amount of the resin composition for element encapsulation for organic electronic devices. If the amount of incorporation is less than 5%, the effect of decreasing the viscosity is reduced. If the amount of incorporation is more than 30% by mass, since the cohesive force of the composition decreases, the amount of extrusion may increase.

[Other Additives]

The transparent resin composition for organic EL element encapsulation may include a silane coupling agent. When a silane coupling agent is used, the amount of chemical bonding to an adherend such as glass is increased, and the adhesive force is enhanced. Specific examples of the silane coupling agent include silane coupling agents such as 3-glycidoxypropyltrimethoxysilane, 3-glycidoxypropylmethyldimethoxysilane, 3-glycidoxypropylmethyldimethoxysilane, 2-(3,4-epoxycyclohexyl)ethyltrimethoxysilane, N-phenyl-γ-aminopropyltrimethoxysilane, N-(2-aminoethyl)-3-aminopropylmethyldimethoxysilane, N-(2-aminoethyl)-3-aminopropylmethyltrimethoxysilane, 3-aminopropyltriethoxysilane, 3-mercaptopropyltrimethoxysilane, vinyltrimethoxysilane, N-(2-(vinylbenzylamino)ethyl)-3-aminopropyltrimethoxysilane hydrochloride, and 3-methacryloxypropyltrimethoxysilane. These silane coupling agents may be used as mixtures of two or more kinds thereof. The content of the silane coupling agent is preferably 0.05% to 10% by mass, and more preferably 0.1 to 1% by mass, relative to the total amount of the transparent resin composition for organic EL element encapsulation.

(Hydrolysis Retardant)

Furthermore, an amine-based compound such as aniline can be incorporated as a hydrolysis retardant in an amount of 0.1% to 5% by mass relative to the total amount of the transparent resin composition for organic EL element encapsulation, as long as the amount of addition is to an extent that does not impair transparency or moisture permeability.

As long as the purpose of the present invention can be achieved, other components, for example, a storage stabilizer, an oxidation inhibitor, a plasticizer, a tack modifier, and a resin stabilizer, can be further added; however, since there is a possibility that visibility of the image display device may be deteriorated by the moisture or impurities present in those additive components, caution should be taken.

The transparent resin composition for organic EL element encapsulation has a water content according to the Karl-Fischer method defined in JIS K 0068 of 1000 ppm or less, more preferably 500 ppm or less, and even more preferably 100 ppm or less. There are no particular limitations on the lower limit of the water content; however, a water content of 30 ppm or more is practical. By suppressing the water content according to the Karl-Fischer method to 1000 ppm or less, the water included in the sealing layer itself can be prevented from affecting the element, and as a result, deterioration of the encapsulated element for organic electronic devices can be sufficiently delayed.

In order to adjust the water content according to the Karl-Fischer method of the resin composition for element encapsulation for organic electronic devices to 1000 ppm or less, it is desirable to incorporate an organometallic compound and capture the moisture in the resin composition by means of the organometallic compound. Furthermore, in order to allow the resin composition to have a small water content, it is desirable to perform a treatment of drying the resin composition by adding silica gel or the like and then removing the silica gel using a filter. Furthermore, the moisture, solvent and volatile organic molecules in the transparent resin composition for organic EL element encapsulation may also be eliminated using a dryer such as a conical dryer or an evaporator, or in a case in which the resin composition has been processed into a film form, using a drying furnace.

The transparent resin composition for organic EL element encapsulation may include a solvent on the occasion of obtaining a film-like sealing layer 3. Examples of such a solvent include organic solvents such as methyl ethyl ketone, toluene, ethanol, and isopropanol, and methyl ethyl ketone and toluene are particularly preferred. A resin solution obtained by adding the individual materials to be included in the resin composition, to such a solvent and mixing and dispersing the mixture, is applied on the releasable surface of the substrate sheet 2 directly or by transfer, according to a generally known method such as a roll knife coater, a gravure coater, a die coater, a reverse coater, or the like, and the resin solution is dried. Thus, the sealing layer 3 can be obtained.

Furthermore, regarding a technique for obtaining a film-like sealing layer 3 without using an organic solvent, the sealing layer 3 can be obtained by melting the transparent resin composition for organic EL element encapsulation at a high temperature, extruding the composition by a generally known technique such as a hot melt coater, and then cooling the resin composition.

The thickness of the sealing layer 3 is preferably 0.5 to 100 μm, and more preferably 1 to 50 μm.

Furthermore, it is more preferable that the surface roughness Ra of the sealing layer 3 and the object of pasting to be brought into contact with the sealing layer 3, is 2 μm or less. If this surface roughness is more than 2 μm, even if the conformity of the transparent resin composition for organic EL element encapsulation itself is high, the possibility that the sealing layer 3 may not conform to the surface of the object of pasting is increased. For this reason, when the surface roughness is in an appropriate range, the sealing layer 3 and the object of pasting are closely adhered, and therefore, visibility is enhanced. The surface roughness of the object of pasting can be changed by polishing or surface treatment, and the surface roughness of the sealing layer 3 can be modified by changing the surface roughness of the cooling roll when the sealing layer is formed into a film form, or by changing the surface roughness of the release film 4.

The resin sheet for element encapsulation for organic electronic devices 1 may include two or more sealing layers 3, and may have a layer other than the sealing layer 3. As the layer other than the sealing layer 3, for example, a gas barrier film, a glass plate, a metal plate, a metal foil or the like may be pasted by compression to the surface of the sealing layer 3 on the opposite side of the substrate sheet 1 (surface on the reverse side of the surface that is pasted to the element for organic electronic devices). In this case, the release film 4 may not be provided. Particularly, it is preferable to provide a sealing substrate for encapsulating the element for organic electronic devices together with the sealing layer on the surface of the sealing layer 3 on the opposite side of the substrate sheet 1 of the sealing layer 3 (surface on the reverse side of the surface that is pasted to the element for organic electronic devices).

The sealing layer 3 preferably has a moisture permeability of less than 100 μm·g/m²·day. If the moisture permeability is 100 μm·g/m²·day or more, the effect of encapsulating organic EL elements is reduced, and therefore, it is not preferable.

[Method for Measuring Moisture Permeability]

The moisture permeability of the sealing layer 3 can be measured by the method defined in JIS Z 0208 (cup method). Measurement is carried out using a thermo-hygrostat chamber under the conditions of 40° C. and 90% RH.

In order to have a moisture permeability of the sealing layer 3 of less than 100 μm·g/m²·day, it is desirable to add a desiccant such as an organometallic compound, which is capable of removing moisture in the resin, in addition to the use of a material with low water permeability.

Also, for the transparent resin composition for organic EL element encapsulation, it is preferable that the moisture permeability is less than 100 μm·g/m²·day. The moisture permeability of the transparent resin composition for organic EL element encapsulation is measured as follows. A sample for moisture permeability measurement is produced by applying a transparent resin composition to a thickness of 20 μm on a Cellophane having a thickness of 20 μm that has not been subjected to a moisture-proof treatment. Next, calcium chloride is introduced into a cup for moisture permeability measurement, subsequently the Cellophane surface of the sample for moisture permeability measurement is attached to the cup for moisture permeability measurement, and the moisture permeability is calculated from the weight change after storage for 24 hours in a thermo-hygrostat chamber (40° C., 90% RH). The moisture permeability related to the present invention is calculated by the following formula (1). Also, in order to exclude any influence caused by moisture absorption by a Cellophane that has not been subjected to a moisture-proof treatment or the like, measurement is conducted using a cup attached with a Cellophane that has not been subjected to a moisture-proof treatment only, as a reference, and the value of the moisture permeability is corrected.

Moisture permeability (μm·g/m²·day)={[W₁−W₀]×t}/{S×D} (1)

W₀ (g): Mass of the cup before being taken into the thermo-hygrostat chamber

W₁ (g): Mass of the cup after being taken into the thermo-hygrostat chamber

t (μm): Overall thickness of the transparent resin composition and the Cellophane

S (m²): Area of the opening of the cup for moisture permeability measurement

D (day): Days of test

The sealing layer 3 preferably has a light transmittance of 85% or higher for light having a wavelength of 550 nm. It is because if the light transmittance for light at 550 nm is less than 85%, visibility is decreased. The light transmittance can be selected by appropriately selecting the resin.

[Method for Measuring Light Transmittance]

Light transmittance can be determined by measuring the amount of transmitted light using a spectrophotometer (manufactured by Hitachi High-Technologies Corp., Spectrophotometer U-4100 type solid sample analysis system).

Also for the transparent resin composition for organic EL element encapsulation, it is preferable that the light transmittance for light having a wavelength of 550 nm is 85% or higher. In the method for measuring the light transmittance of the transparent resin composition for organic EL element encapsulation, the transparent resin composition is applied to a thickness of 20 μm on an alkali-free glass plate, light is allowed to penetrate in a direction normal to the glass surface, and the light transmittance of the glass plate for light at 550 nm at 25° C. is determined. Specifically, the light transmittance is calculated by the following formula (2):

Light transmittance I(%)=I₁/I₀ (2)

I₁ (%): Light transmittance of glass including the resin composition

I₀ (%): Light transmittance of glass

Regarding the sealing layer 3, the amount of extrusion obtainable after leaving the sealing layer to stand for 150 hours under the conditions of a temperature of 85° C. and a relative humidity of 85% in a state of being encapsulated between two sheets of glass plates, is preferably less than 2 mm, and more preferably less than 1.5 mm.

An organic light emitting diode (OLED) may be subjected to a high temperature (for example, 85° C.) in a reliability evaluation test or the like, and at that time, if the sealing layer 3 in a state of being encapsulated from the outer periphery of the organic EL element becomes less viscous and is extruded, there is a risk that the sealing layer may contaminate the organic EL element or components in the periphery of the element. This amount of extrusion is one item of simple evaluation for the lamination properties, and if the amount of extrusion is 2 mm or more, the resin has high fluidity, and this leads to contamination of the peripheral region of the element. If the amount of extrusion is less than 2 mm, no problem occurs in connection with the lamination properties.

In order to adjust the amount of extrusion to less than 2 mm, it is necessary to design the composition so as to make the transparent resin composition for organic EL element encapsulation more viscous, and it is effective to have a molecular weight of the polyisobutylene of 300,000 or more, to adjust the softening temperature of the tackifying agent to 60° C. or higher, and to add an organometallic compound.

Also, in regard to the transparent resin composition for organic EL element encapsulation, the amount of extrusion obtainable after leaving the resin composition to stand for 150 hours under the conditions of a temperature of 85° C. and a relative humidity of 85% in a state of being encapsulated between two sheets of glass plates, is preferably less than 2 mm, and more preferably less than 1.5 mm.

<Method of Use>

Next, the method of using the resin sheet for element encapsulation for organic electronic devices 1 will be explained.

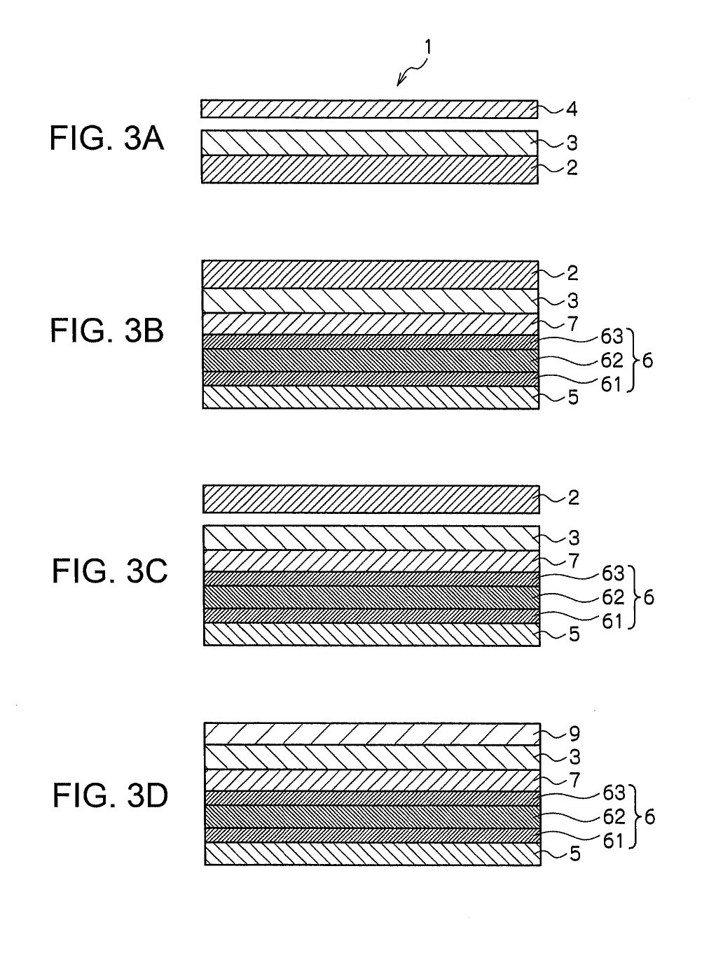

The resin sheet for element encapsulation for organic electronic devices 1 of the present invention is disposed between an organic EL element 6 that is provided on an element substrate 5 (see FIGS. 2 and 3B-3D) and a sealing substrate 9 (see FIGS. 2 and 3D), and is used to obtain various organic electronic devices having a solid cohesively encapsulated structure by encapsulating the organic EL element 6 in an air-tight manner with the element substrate 5 and the sealing substrate 9. Examples of the organic electronic devices include organic EL displays, organic EL lightings, organic semiconductors, and organic solar cells.

Hereinafter, an organic EL display (image display device) will be explained as an example of the organic electronic devices. In an organic EL display 11, as illustrated in FIG. 2, an organic EL element 6 provided on an element substrate 5 is encapsulated by a sealing substrate 9, with a transparent resin layer for organic EL element encapsulation 8 (sealing layer 3 in an encapsulated state) being interposed therebetween.

The organic EL element 6 includes, for example, as illustrated in FIG. 2, an anode 61 formed by patterning a conductive material, an organic layer 62 formed by a thin film of an organic compound material and laminated on the surface of the anode 61, and a cathode 63 laminated on the surface of the organic layer 62 and formed by patterning a transparent conductive material, on an element substrate 5 formed from a glass substrate or the like. Meanwhile, parts of the anode 61 and the cathode 63 protrude from an edge of the element substrate 5 and are connected to a driving circuit that is not illustrated in the diagram. The organic layer 62 is formed by laminating a hole injection layer, a hole transport layer, a light emitting layer, and an electron transport layer in this order from the anode 61 side, and the light emitting layer is formed by laminating a blue light emitting layer, a green light emitting layer, and a red light emitting layer. Meanwhile, the light emitting layer may also have non-luminescent intermediate layers between the various light emitting layers of blue, green and red colors. Furthermore, after the organic layer 62 and the cathode 63 are formed, when organic and inorganic thin films having gas barrier properties are formed so as to cover these organic layer and cathode, it is more effective for preventing deterioration of the organic light emitting device, together with the effect of the transparent resin layer for organic EL element encapsulation 8. In the organic EL display 11, a barrier-like thin film layer 7 formed from an inorganic compound is formed on the surface of the cathode 63, and a transparent resin layer for organic EL element encapsulation 8 is provided on the barrier-like thin film layer 7.

For the sealing substrate 9, any material having properties that do not seriously inhibit visibility of the display content of the organic EL display 11 may be used, and for example, glass or a resin can be used.

Next, the barrier-like thin film layer 7 formed from an inorganic compound will be explained. The barrier-like thin film layer formed from an inorganic compound is intended to prevent permeation of gas such as water vapor or oxygen. The material that forms the barrier-like thin film layer is not particularly limited, and any transparent material having gas barrier properties against oxygen or water vapor, such as oxides, nitrides, fluorides of metals such as silicon, aluminum, chromium or magnesium; composite oxides or nitrides such as tin-containing indium oxide (ITO), can be used. Among them, metal oxides can be preferably used, and aluminum oxide (Al₂O₃), silicon oxide (SiOₓ), and a composite oxide of indium and tin (ITO) are desirable, while among them, SiOₓ and ITO are more preferred because these oxides are superior to other metal oxides in view of transparency and moisture-proof properties. Furthermore, SiOₓN_{y} containing a slight amount of nitrogen is also acceptable. A mixed material is also acceptable.

There are various methods for forming a barrier-like thin film layer 7 formed from a metal oxide or the like on a substrate film, and the barrier-like thin film layer 7 can be formed by a vacuum deposition method such as a resistance heating type vacuum deposition method, an EB (electron beam) heating type vacuum deposition method, or an induction heating type vacuum deposition method. Furthermore, other thin film-forming methods such as a sputtering method, an ion plating method, and a plasma-enhanced chemical vapor deposition method (PECVD method) can also be used. However, when productivity is considered, a vacuum deposition method is most excellent at the present moment. Regarding the heating means for the vacuum deposition method, it is preferable to use any system such as an electron beam heating system, a resistance heating system, or an induction heating system. Furthermore, in order to further enhance the adhesiveness between the vapor-deposited thin film layer and the substrate, and the compactness of the vapor-deposited thin film layer, vapor deposition can also be achieved using a plasma assisted method or an ion beam assisted method. Furthermore, reactive vapor deposition of blowing various gases such as oxygen may also be used without any problem, at the time of performing vapor deposition in order to increase transparency of the vapor-deposited film.

Although the optimal conditions may vary depending on the kind and composition of the inorganic compound used, the thickness of the gas barrier-like thin film layer 7 is generally preferably in the range of 1.0 nm to 300 nm, more preferably from 5 nm to 100 nm, and particularly preferably from 10 nm to 80 nm. However, if the film thickness is less than 5 nm, a uniform film may not be obtained, or the film thickness may not be sufficient. Thus, the gas barrier-like thin film layer may not be able to sufficiently accomplish the function as a gas barrier material. Furthermore, if the film thickness is more than 100 nm, the thin film cannot maintain flexibility, and there is a risk that fissures (cracks) may occur in the thin film due to external factors such as folding, stretching, or expansion or contraction caused by temperature change, which causes a problem. Furthermore, the cost is increased due to an increase in the amount of the materials used, lengthening of the film-forming time, or the like, and it is not also preferable from the viewpoint of economic efficiency.

Next, the transparent resin layer for organic EL encapsulation 8 that is formed on the barrier-like thin film layer 7 will be explained.

The transparent resin layer for organic EL element encapsulation 8 is formed using the resin composition for element encapsulation for organic electronic devices described above, or the resin sheet for element encapsulation for organic electronic devices 1, and can be formed by the following process. In the case of using a resin composition for element encapsulation for organic electronic devices, the resin composition can be directly applied on the barrier-like thin film layer 7 using a dispenser or the like. On the other hand, in a case in which the resin sheet for element encapsulation for organic electronic devices 1 obtained by processing the resin composition into sheets is used, first, as illustrated in FIG. 3A, the release film 4 of the resin sheet for element encapsulation for organic electronic devices 1 is peeled off, and as illustrated in FIG. 3B, the sealing layer 3 is roll-pasted to the sealing substrate 9. Next, as illustrated in FIG. 3C, the substrate sheet 2 of the resin sheet for element encapsulation for organic electronic devices 1 pasted to the sealing substrate 9 is peeled off. Thereafter, as illustrated in FIG. 3D, the sealing layer 3 of the resin sheet for element encapsulation for organic electronic devices 1 pasted to the sealing substrate 9 is laminated on the cathode 63 side of the organic EL element 6, with a barrier-like thin film layer 7 being interposed therebetween. The sealing layer 3 of the resin sheet for element encapsulation for organic electronic devices 1 constitutes the transparent resin layer for organic EL element encapsulation 8 in the organic EL display 111.

It is preferable that the pasting and lamination described above are carried out at a temperature of 100° C. or lower. If the temperature exceeds 100° C., the constituent materials of the organic EL element 6 are deteriorated, and there is a risk that the light emission characteristics may be deteriorated.

Meanwhile, in the process for forming the transparent resin layer for organic EL element encapsulation 8, the resin sheet for element encapsulation for organic electronic devices 1 is initially roll-pasted to the sealing substrate 9; however, the resin sheet may also be pasted to the organic EL element 6. In this case, the substrate sheet 2 of the resin sheet for element encapsulation for organic electronic devices 1 is peeled off, and then the sealing layer 3 is laminated to the sealing substrate 9.

According to an embodiment, a gas barrier film having water vapor barrier characteristics is used. A flexible material suitable for the substrate is a resin material, and examples thereof include a fluorine-containing polymer, for example, polyethylene trifluoride, polychlorotrifluoroethylene (PCTFE), a copolymer of vinylidene fluoride (VDF) and chlorotrifluoroethylene (CTFE); a polyimide, a polycarbonate, polyethylene terephthalate, an alicyclic polyolefin, and an ethylene-vinyl alcohol copolymer. The substrate can be coated with a gas barrier inorganic film containing an inorganic material such as SiO, SiN, or DLC (diamond-like carbon). The inorganic film can be formed using a method such as vacuum gas phase deposition, sputtering, or plasma CVD (chemical gas phase film-forming method). Other materials that are not specifically described in the present specification can also be used.

Furthermore, a gas barrier film may be interposed between the sealing layer 3 and the sealing substrate 9, or a resin sheet for element encapsulation for organic electronic devices 1 having a gas barrier film pasted in advance on the surface of the sealing layer 3 opposite to the substrate sheet 2 may also be used. In the case of using a resin sheet for element encapsulation for organic electronic devices 1 having a gas barrier film pasted in advance on the surface of the sealing layer 3 opposite to the substrate sheet 2, an organic EL element attached with a gas barrier film and a sealing layer 3 is produced by peeling off the substrate sheet 2 and then pasting the sealing layer 3 to the organic EL element 6.

Furthermore, in the case of using a resin sheet for element encapsulation for organic electronic devices 1 having a sealing substrate pasted in advance on the surface of the sealing layer 3 opposite to the substrate sheet 2, it is not necessary to roll-paste the resin sheet to the sealing substrate 8 as described above, and it is still acceptable to peel off the substrate sheet 2 of the resin sheet for element encapsulation for organic electronic devices 1 to which the sealing substrate has been pasted in advance, and to laminate the exposed sealing layer 3 on the cathode 63 side of the organic EL element 6.

Hereinafter, the configuration of the present invention is described in more detail by way of Examples, but the present invention is not intended to be limited to these.

(Raw Materials)

<Polyisobutylene Resin>

A1: OPPANOL B150 (manufactured by BASF SE: polyisobutylene resin, mass average molecular weight Mw 2,500,000)

A2: OPPANOL B100 (manufactured by BASF SE: polyisobutylene resin, mass average molecular weight Mw 1,100,000)

A3: OPPANOL B80 (manufactured by BASF SE: polyisobutylene resin, mass average molecular weight Mw 750,000)

A4: OPPANOL B50 (manufactured by BASF SE: polyisobutylene resin, mass average molecular weight Mw 340,000)

A5: OPPANOL B30 (manufactured by BASF SE: polyisobutylene resin, mass average molecular weight Mw 280,000)

A6: GLISSOPAL V1500 (manufactured by BASF SE: polyisobutylene resin, mass average molecular weight Mw 4140)

<Tackifying Resin>

B1: I-MARV P100 (manufactured by Idemitsu Kosan Co., Ltd.: fully hydrogenated petroleum resin, molecular weight 660)

B2: I-MARV P140 (manufactured by Idemitsu Kosan Co., Ltd.; fully hydrogenated petroleum resin, molecular weight 900)

B3: CLEARON P105 (manufactured by Yasuhara Chemical Co., Ltd.; hydrogenated terpene resin)

B4: PINE CRYSTAL KE311 (manufactured by Arakawa Chemical Industries, Ltd.; hydrogenated rosin ester)

B5: PETROTACK 90 (manufactured by Tosoh Corp.: petroleum resin, molecular weight 900)

<Organometallic Compound>

C1: ALCH (manufactured by Kawaken Fine Chemicals Co., Ltd.: aluminum ethyl acetoacetate diisopropylate, molecular weight 274)

C2: ALCH-TR (manufactured by Kawaken Fine Chemicals Co., Ltd.: aluminum trisethyl acetoacetate, molecular weight 414.4)

C3: OLIPE AOS (manufactured by Hope Chemical Co., Ltd.: aluminum oxide stearate, molecular weight 379.4)

C4: OLIPE C10-2 (manufactured by Hope Chemical Co., Ltd.: aluminum bis(2-methylnonyloxy)monoethyl acetoacetate, molecular weight 470)

C5: Aluminum Chelate A(W) (manufactured by Kawaken Fine Chemicals Co., Ltd.: aluminum tris(acetyl acetonate), molecular weight 324.3)

### Example 1

32 parts by weight of a polyisobutylene resin (OPPANOL B150, manufactured by BASF SE), 48 parts by weight of a fully hydrogenated petroleum resin (I-MARV P100, manufactured by Idemitsu Kosan Co., Ltd.), and an appropriate amount of toluene were introduced into a container, and the mixture was sufficiently stirred. Subsequently, in a nitrogen atmosphere, 20 parts by weight of aluminum ethyl acetoacetate diisopropylate (ALCH, manufactured by Kawaken Fine Chemicals Co., Ltd.) was added to the mixture, the mixture was further stirred, and thus a resin composition was obtained. This resin composition thus prepared was applied on a peeled surface of a peelable-treated polyester film (manufactured by DuPont-Teijin Films, Ltd., PUREX A-314) having a thickness of 50 μm as a substrate sheet such that the film thickness after drying would be 20 μm, and the resin composition was dried for several minutes at 120° C. Furthermore, this dried surface was laminated with a release-treated surface of a polyester film (manufactured by Toyobo Co., Ltd., TOYOBO ESTER FILM E7006) having a thickness of 25 μm, which had been subjected to a silicone release treatment, as a release film, and thus a transparent resin sheet for organic EL element encapsulation related to Example 1 was produced.

### Examples 2 to 43

Resin sheets for element encapsulation for organic electronic devices related to Examples 2 to 43 were produced in the same manner as in Example 1, except that the blend compositions indicated in Tables 1 to 3 were used.

### Comparative Examples 1 to 9

Resin sheets for organic EL element encapsulation related to Comparative Examples 1 to 9 were produced in the same manner as in Example 1, except that the blend compositions indicated in Table 4 were used.

(Measurement Methods and Evaluation Methods)

Measurement and evaluations were carried out according to the following measurement methods and evaluation methods. The results are presented in Tables 1 to 4.

<Water Content>

For the sealing layer from which a release film and a substrate sheet were peeled off in each of the resin sheets for element encapsulation for organic electronic devices related to various Examples and Comparative Examples, the water content was measured according to the Karl-Fischer method based on the moisture vaporization-coulometric titration method defined in JIS K 0068. The set heating temperature was 150° C.

<Moisture Permeability>

For the resin compositions for element encapsulation for organic electronic devices used in various Examples and Comparative Examples, measurement was carried out by emulating the method defined in JIS Z 0208 (cup method), under the conditions of 40° C. and 90% RH using a thermo-hygrostat chamber. The moisture permeability of the transparent resin composition for organic EL element encapsulation was measured as follows. First, a transparent resin composition was applied to a thickness of 20 μm on a Cellophane having a thickness of 20 μm that had not been subjected to a moisture-proof treatment, and thereby a sample for moisture permeability measurement was produced. Next, calcium chloride was introduced into a cup for moisture permeability measurement, subsequently the Cellophane surface of the sample for moisture permeability measurement was attached to the cup for moisture permeability measurement, and the moisture permeability was calculated from the weight change after storage for 24 hours in a thermo-hygrostat chamber (40° C., 90% RH). The moisture permeability related to the present invention was calculated by the following formula (1). Furthermore, in order to exclude any influence caused by moisture absorption by a Cellophane that had not been subjected to a moisture-proof treatment or the like, measurement was conducted using a cup attached with a Cellophane that had not been subjected to a moisture-proof treatment only, as a reference, and the value of the moisture permeability was corrected.

Moisture permeability (μm·g/m²·day)={[W₁−W₀]×t}/{S×D} (1)

W₀ (g): Mass of the cup before being taken into the thermo-hygrostat chamber

W₁ (g): Mass of the cup after being taken into the thermo-hygrostat chamber

t (μm): Overall thickness of the transparent resin composition and the Cellophane

S (m²): Area of the opening of the cup for moisture permeability measurement

D (day): Days of test

<Light Transmittance>

Each of the resin compositions for element encapsulation for organic electronic devices used in various Examples sand Comparative Examples was applied on an alkali-free glass plate for LCD (OA-10G manufactured by Nippon Electric Glass Co., Ltd.) to a thickness of 20 μm, and light was allowed to penetrate in the direction normal to the glass surface. Thus, the light transmittance at 550 nm at 25° C. was determined. Light transmittance was determined using a spectrophotometer (Spectrophotometer U-4100 type solid sample analysis system manufactured by Hitachi High-Technologies Corp.), and was calculated by the following formula (2).

Light transmittance I(%)=I₁/I₀ (2)

I₁(%): Light transmittance of glass including the resin composition

I₀(%): Light transmittance of glass

<Amount of Extrusion>

First, a polyethylene terephthalate film (manufactured by Mitsui Chemicals, Inc.) which measured 4 mm×5 mm×25 μm in thickness was superimposed on the transparent resin composition for organic EL element encapsulation used in each of Examples and Comparative Examples, and the resultant was disposed between two sheets of micro-slide glasses (S9213, 76 mm×52 mm, 1.3 mm in thickness) manufactured by Matsunami Glass Industry, Ltd. The glass-glass encapsulated body thus obtained was left to stand for 150 hours in a high-temperature high-humidity test under the conditions of a temperature of 85° C. and a relative humidity of 85%, and the amount of extrusion of the encapsulated sealing layer was measured. The portion extruded from the polyethylene terephthalate film was observed with an optical microscope, and the maximum value of the length of the sealing layer extruding from each side of the polyethylene terephthalate film in a direction perpendicular to each side of the polyethylene terephthalate film, was designated as the amount of extrusion.

<Dark Spot>

Organic EL elements of bottom emission type and top emission type were produced, each of which had an anode on an element substrate formed from an insulating transparent glass plate, and also had an organic layer on top of the anode, a cathode on top of the organic layer, and an organic/inorganic transparent composite thin film on top of the cathode. Subsequently, the release film of the transparent resin sheet for organic EL element encapsulation related to each of the Examples and Comparative Examples was peeled off, and the transparent resin sheet was disposed on the surface of the cathode of each of the organic EL elements described above. Thereafter, the substrate sheet of the transparent resin sheet for organic EL element encapsulation was peeled off, an insulating transparent glass plate as a sealing substrate was disposed on the surface of the sealing layer of the transparent resin sheet for organic EL element encapsulation, and the assembly was pressed at a pressure of 0.6 MPa for 1 minute under reduced pressure and at 80° C. Thus, an organic EL display model was produced.

Next, the model was left to stand for 24 hours and for 500 hours under the conditions of a temperature of 85° C. and a relative humidity of 85%, and then the model was cooled to room temperature (25° C.). The organic EL element was operated by passing electricity at a voltage of 10 V, and dark spots (non-light emitting sites) were observed. A case in which the area of dark spots was less than 5% of the whole area was rated as “A”, for having an excellent ability of suppressing the occurrence of dark spots; a case in which the area was 5% or more but less than 10% was rated as “B”; a case in which the area was 10% or more but less than 20% was rated as “C”; and a case in which the area was 20% or more was rated as “D”, for having an inferior ability of suppressing the occurrence of dark spots. Furthermore, when the light transmittance of the resin sheet for element encapsulation for organic electronic devices was decreased, and dark spots could not be clearly recognized, an evaluation was not performed.

TABLE 1

| Component | | Example 1 | Example 2 | Example 3 | Example 4 | Example 5 | Example 6 | Example 7 | Example 8 |
|---|---|---|---|---|---|---|---|---|---|
| Polyisobutylene resin | A1 | 32 | | | | | | 38 | |
| (parts by weight) | A2 | | 38 | 32 | | | | | 38 |
| | A3 | | | | 38 | 32 | 32 | | |
| | A4 | | | | | | | | |
| | A5 | | | | | | | | |
| | A6 | | | | | | | | |
| Tackifying resin | B1 | 48 | 56 | 48 | 56 | 48 | 48 | | |
| (parts by weight) | B2 | | | | | | | | |
| | B3 | | | | | | | | |
| | B4 | | | | | | | 52 | 52 |
| | B5 | | | | | | | | |
| Organometallic | C1 | 20 | 6 | 20 | 6 | 20 | | 10 | 10 |
| compound | C2 | | | | | | 20 | | |
| (parts by weight) | C3 | | | | | | | | |
| | C4 | | | | | | | | |
| | C5 | | | | | | | | |
| Percentage of metal | (wt %) | 1.97 | 0.59 | 1.97 | 0.59 | 1.97 | 1.30 | 0.99 | 0.99 |
| content in resin | | | | | | | | | |
| composition | | | | | | | | | |
| Water content of resin | (ppm) | 30 | 70 | 30 | 60 | 40 | 45 | 50 | 70 |
| composition | | | | | | | | | |
| Moisture permeability | (μm · g/m² · day) | 5 | 25 | 10 | 32 | 20 | 20 | 85 | 60 |
| of resin composition | | | | | | | | | |
| Amount of extrusion | (mm) | 0.05 | 0.6 | 0.2 | 1.0 | 0.2 | 0.2 | 0.4 | 0.8 |
| of resin composition | | | | | | | | | |
| Light transmittance of | (%) | 96 | 99 | 96 | 99 | 96 | 96 | 98 | 97 |
| resin composition | | | | | | | | | |
| Evaluation of dark | 24 Hr | A | A | A | A | A | A | A | A |
| spots | 500 Hr | A | A | A | A | A | A | A | A |
| Bottom emission | | | | | | | | | |
| system | | | | | | | | | |
| Evaluation of dark | 24 Hr | A | A | A | A | A | A | A | A |
| spots | 500 Hr | A | A | A | A | A | A | A | A |
| Top emission system | | | | | | | | | |

| | | | Example | Example | Example | Example | Example | Example |
|---|---|---|---|---|---|---|---|---|
| Component | | Example 9 | 10 | 11 | 12 | 13 | 14 | 15 |
| Polyisobutylene resin | A1 | | | 14 | | | 78 | |
| (parts by weight) | A2 | | | | 14 | | | |
| | A3 | 38 | 38 | | | 14 | | 78 |
| | A4 | | | | | | | |
| | A5 | | | | | | | |
| | A6 | | | | | | | |
| Tackifying resin | B1 | | | 76 | 76 | 76 | 12 | 12 |
| (parts by weight) | B2 | | | | | | | |
| | B3 | 52 | | | | | | |
| | B4 | | 52 | | | | | |
| | B5 | | | | | | | |
| Organometallic | C1 | 10 | 10 | 10 | 10 | 10 | 10 | 10 |
| compound | C2 | | | | | | | |
| (parts by weight) | C3 | | | | | | | |
| | C4 | | | | | | | |
| | C5 | | | | | | | |
| Percentage of metal | (wt %) | 0.99 | 0.99 | 0.99 | 0.99 | 0.99 | 0.99 | 0.99 |
| content in resin | | | | | | | | |
| composition | | | | | | | | |
| Water content of resin | (ppm) | 80 | 75 | 40 | 50 | 75 | 30 | 60 |
| composition | | | | | | | | |
| Moisture permeability | (μm · g/m² · day) | 60 | 70 | 45 | 45 | 45 | 65 | 50 |
| of resin composition | | | | | | | | |
| Amount of extrusion | (mm) | 1.2 | 1.2 | 0.1 | 0.7 | 0.8 | 0.2 | 1.2 |
| of resin composition | | | | | | | | |
| Light transmittance of | (%) | 98 | 98 | 99 | 99 | 99 | 99 | 99 |
| resin composition | | | | | | | | |
| Evaluation of dark | 24 Hr | A | A | A | A | A | A | A |
| spots | 500 Hr | A | A | B | B | B | B | B |
| Bottom emission | | | | | | | | |
| system | | | | | | | | |
| Evaluation of dark | 24 Hr | A | A | A | A | A | A | A |
| spots | 500 Hr | A | A | B | B | B | B | B |
| Top emission system | | | | | | | | |

TABLE 2

| | | Example | Example | Example | Example | Example | Example | Example | Example |
|---|---|---|---|---|---|---|---|---|---|
| Component | | 16 | 17 | 18 | 19 | 20 | 21 | 22 | 23 |
| Polyisobutylene resin | A1 | | | | | 38 | 40 | 38 | |
| (parts by weight) | A2 | | | | | | | | 38 |
| | A3 | | | | | | | | |
| | A4 | 32 | 32 | 38 | 38 | | | | |
| | A5 | | | | | | | | |
| | A6 | | | | | | | | |
| Tackifying resin | B1 | 48 | 48 | | 52 | 57 | 59 | 57 | 57 |
| (parts by weight) | B2 | | | 52 | | | | | |
| | B3 | | | | | | | | |
| | B4 | | | | | | | | |
| | B5 | | | | | | | | |
| Organometallic | C1 | | 20 | 10 | 10 | 5 | 0.7 | | |
| compound | C2 | 20 | | | | | | 5 | 5 |
| (parts by weight) | C3 | | | | | | | | |
| | C4 | | | | | | | | |
| | C5 | | | | | | | | |
| Percentage of metal | (wt %) | 1.30 | 1.97 | 0.99 | 0.99 | 0.49 | 0.07 | 0.33 | 0.33 |
| content in resin | | | | | | | | | |
| composition | | | | | | | | | |
| Water content of resin | (ppm) | 130 | 110 | 350 | 400 | 230 | 400 | 250 | 220 |
| composition | | | | | | | | | |
| Moisture permeability | (μm · g/m² · day) | 30 | 30 | 45 | 40 | 50 | 65 | 55 | 55 |
| of resin composition | | | | | | | | | |
| Amount of extrusion | (mm) | 1.6 | 1.6 | 1.7 | 1.6 | 0.1 | 0.1 | 0.1 | 0.6 |
| of resin composition | | | | | | | | | |
| Light transmittance of | (%) | 96 | 96 | 99 | 99 | 99 | 99 | 99 | 99 |
| resin composition | | | | | | | | | |
| Evaluation of dark | 24 Hr | B | B | B | B | B | B | B | B |
| spots | 500 Hr | B | B | B | B | B | B | B | B |
| Bottom emission | | | | | | | | | |
| system | | | | | | | | | |
| Evaluation of dark | 24 Hr | B | B | B | B | B | B | B | B |
| spots | 500 Hr | B | B | B | B | B | B | B | B |
| Top emission system | | | | | | | | | |

| | | Example | Example | Example | Example | Example | Example | Example |
|---|---|---|---|---|---|---|---|---|
| Component | | 24 | 25 | 26 | 27 | 28 | 29 | 30 |
| Polyisobutylene resin | A1 | | | | | | | |
| (parts by weight) | A2 | | | | | | | |
| | A3 | 40 | 38 | | | | | |
| | A4 | | | 85 | 14 | 40 | 38 | 38 |
| | A5 | | | | | | | |
| | A6 | | | | | | | |
| Tackifying resin | B1 | 59 | 57 | 10 | 81 | 60 | | |
| (parts by weight) | B2 | | | | | | | |
| | B3 | | | | | | 57 | |
| | B4 | | | | | | | 57 |
| | B5 | | | | | | | |
| Organometallic | C1 | 0.7 | | 5 | 5 | 1 | 5 | 5 |
| compound | C2 | | 5 | | | | | |
| (parts by weight) | C3 | | | | | | | |
| | C4 | | | | | | | |
| | C5 | | | | | | | |
| Percentage of metal | (wt %) | 0.07 | 0.33 | 0.49 | 0.49 | 0.05 | 0.49 | 0.49 |
| content in resin | | | | | | | | |
| composition | | | | | | | | |
| Water content of resin | (ppm) | 250 | 200 | 620 | 500 | 880 | 550 | 600 |
| composition | | | | | | | | |
| Moisture permeability | (μm · g/m² · day) | 70 | 60 | 60 | 80 | 80 | 70 | 80 |
| of resin composition | | | | | | | | |
| Amount of extrusion | (mm) | 1.0 | 1.0 | 1.4 | 1.2 | 1.3 | 1.3 | 1.3 |
| of resin composition | | | | | | | | |
| Light transmittance of | (%) | 99 | 99 | 99 | 99 | 99 | 99 | 99 |
| resin composition | | | | | | | | |
| Evaluation of dark | 24 Hr | A | B | B | B | B | B | B |
| spots | 500 Hr | B | B | C | C | C | C | C |
| Bottom emission | | | | | | | | |
| system | | | | | | | | |
| Evaluation of dark | 24 Hr | A | B | B | B | B | B | B |
| spots | 500 Hr | B | B | C | C | C | C | C |
| Top emission system | | | | | | | | |

TABLE 3

| | | Example | Example | Example | Example | Example | Example | Example |
|---|---|---|---|---|---|---|---|---|
| Component | | 31 | 32 | 33 | 34 | 35 | 36 | 37 |
| Polyisobutylene resin | A1 | | | | | | | 33 |
| (parts by weight) | A2 | | | 38 | 38 | | | |
| | A3 | | | | | 38 | | |
| | A4 | 40 | 38 | | | | 38 | |
| | A5 | | | | | | | |
| | A6 | | | | | | | |
| Tackifying resin | B1 | 60 | 57 | | | | | 42 |
| (parts by weight) | B2 | | | | | | | |
| | B3 | | | | | | | |
| | B4 | | | | | | | |
| | B5 | | | 52 | 52 | 52 | 52 | |
| Organometallic | C1 | | | 10 | | 10 | 10 | |
| compound | C2 | 1 | 5 | | 10 | | | |
| (parts by weight) | C3 | | | | | | | |
| | C4 | | | | | | | 25 |
| | C5 | | | | | | | |
| Percentage of metal | (wt %) | 0.03 | 0.33 | 0.99 | 0.65 | 0.99 | 0.99 | 1.44 |
| content in resin | | | | | | | | |
| composition | | | | | | | | |
| water content of resin | (ppm) | 880 | 910 | 85 | 90 | 85 | 85 | 50 |
| composition | | | | | | | | |
| Moisture permeability of | (μm · g/m² · day) | 70 | 70 | 40 | 45 | 40 | 45 | 35 |
| resin composition | | | | | | | | |
| Amount of extrusion of | (mm) | 1.4 | 1.3 | 0.8 | 0.8 | 1.0 | 1.4 | 0.8 |
| resin composition | | | | | | | | |
| Light transmittance of | (%) | 99 | 99 | 87 | 88 | 88 | 88 | 67 |
| resin composition | | | | | | | | |
| Evaluation of dark spots | 24 Hr | B | B | A | A | A | A | A |
| Bottom emission system | 500 Hr | C | C | — | — | — | — | A |
| Evaluation of dark spots | 24 Hr | B | B | A | A | A | A | — |
| Top emission system | 500 Hr | C | C | — | — | — | — | — |

| | | Example | Example | Example | Example | Example | Example |
|---|---|---|---|---|---|---|---|
| Component | | 38 | 39 | 40 | 41 | 42 | 43 |
| Polyisobutylene resin | A1 | | 28 | | | | |
| (parts by weight) | A2 | 38 | | 33 | | | |
| | A3 | | | | | | |
| | A4 | | | | 28 | 21 | 28 |
| | A5 | | | | | | |
| | A6 | | | | | | |
| Tackifying resin | B1 | 50 | 42 | 42 | 42 | | |
| (parts by weight) | B2 | | | | | | |
| | B3 | | | | | | |
| | B4 | | | | | 39 | 42 |
| | B5 | | | | | | |
| Organometallic | C1 | | | | | | |
| compound | C2 | | | | | | |
| (parts by weight) | C3 | | 30 | | 30 | | 30 |
| | C4 | | | | | 40 | |
| | C5 | 12 | | 25 | | | |
| Percentage of metal | (wt %) | 1.00 | 2.13 | 2.08 | 2.13 | 2.30 | 2.13 |
| content in resin | | | | | | | |
| composition | | | | | | | |
| water content of resin | (ppm) | 65 | 35 | 40 | 40 | 35 | 40 |
| composition | | | | | | | |
| Moisture permeability of | (μm · g/m² · day) | 40 | 110 | 130 | 150 | 110 | 110 |
| resin composition | | | | | | | |
| Amount of extrusion of | (mm) | 1.4 | 0.3 | 0.4 | 1.1 | 1.1 | 1.1 |
| resin composition | | | | | | | |
| Light transmittance of | (%) | 67 | 73 | 73 | 74 | 62 | 70 |
| resin composition | | | | | | | |
| Evaluation of dark spots | 24 Hr | A | A | A | A | A | A |
| Bottom emission system | 500 Hr | A | C | C | C | C | C |
| Evaluation of dark spots | 24 Hr | — | — | — | — | — | — |
| Top emission system | 500 Hr | — | — | — | — | — | — |

TABLE 4

| | | Compara- | Compara- | Compara- | Compara- | Compara- | Compara- | Compara- | Compara- | Compara- |
|---|---|---|---|---|---|---|---|---|---|---|
| | | tive | tive | tive | tive | tive | tive | tive | tive | tive |
| Component | | Example 1 | Example 2 | Example 3 | Example 4 | Example 5 | Example 6 | Example 7 | Example 8 | Example 9 |
| Polyisobutylene resin | A1 | 40 | | | | | | | | |
| (parts by weight) | A2 | | | | | | | | | |
| | A3 | | 40 | | | | | | | |
| | A4 | | | | | | | | | |
| | A5 | | | 38 | 38 | | | 40 | | |
| | A6 | | | | | 32 | 40 | | 40 | 40 |
| Tackifying resin | B1 | 60 | 60 | 57 | 57 | 48 | 60 | 60 | | 60 |
| (parts by weight) | B2 | | | | | | | | | |
| | B3 | | | | | | | | | |
| | B4 | | | | | | | | 60 | |
| | B5 | | | | | | | | | |
| Organometallic | C1 | | | 5 | | 20 | 20 | | | |
| compound | C2 | | | | 5 | | | | | |
| (parts by weight) | C3 | | | | | | | | | |
| | C4 | | | | | | | | | |
| | C5 | | | | | | | | | |
| Percentage of metal | (wt %) | 0.00 | 0.00 | 0.49 | 0.33 | 1.97 | 1.97 | 0.00 | 0.00 | 0.00 |
| content in resin | | | | | | | | | | |
| composition | | | | | | | | | | |
| Water content of resin | (ppm) | 1100 | 1300 | 1700 | 1500 | 2100 | 1800 | 1500 | 1600 | 2000 |
| composition | | | | | | | | | | |
| Moisture permeability | (μm · g/m² · day) | 90 | 95 | 95 | 95 | 550 | 600 | 110 | 550 | 1000 |
| of resin composition | | | | | | | | | | |
| Amount of extrusion | (mm) | 1.0 | 1.2 | 1.7 | 1.6 | 2.1 | 2.2 | 2.3 | 2.1 | 3.9 |
| of resin composition | | | | | | | | | | |
| Light transmittance of | (%) | 99 | 99 | 99 | 99 | 96 | 96 | 99 | 96 | 99 |
| resin composition | | | | | | | | | | |
| Evaluation of dark | 24 Hr | D | D | D | D | D | D | D | D | D |
| spots | | | | | | | | | | |
| Bottom emission | 500 Hr | D | D | D | D | D | D | D | D | D |
| system | | | | | | | | | | |
| Evaluation of dark | 24 Hr | D | D | D | D | D | D | D | D | D |
| spots | | | | | | | | | | |
| Top emission system | 500 Hr | D | D | D | D | D | D | D | D | D |

As shown in Tables 1 to 3, since Examples 1 to 43 contained a polyisobutylene resin (A) containing a polyisobutylene skeleton in a main chain or in a side chain and having a weight average molecular weight (Mw) of 300,000 or more, and a tackifying agent (B) as main components, contained an organometallic compound (C) having hygroscopic properties, and had a water content of 1000 ppm or less, satisfactory results were obtained in all of the characteristics of moisture permeability, the amount of extrusion, light transmissibility, and dark spots.

On the contrary, as shown in Table 4, since the organometallic compound represented by Chemical Formula 1 was not included, or even if the organometallic compound represented by formula (1) was included, since the mass average molecular weight (Mw) of the polyisobutylene resin was 300,000 or less, results such as a water content of more than 1000 ppm, a moisture permeability higher than the moisture permeabilities of the Examples, and the generation of dark spots, were obtained. Furthermore, a sample that did not contain the organometallic compound had high fluidity of the sealing layer under high temperature, high humidity conditions, and thus the amount of extrusion was high.

### EXPLANATIONS OF LETTERS OR NUMERALS

1: RESIN SHEET FOR ELEMENT ENCAPSULATION FOR ORGANIC ELECTRONIC DEVICES
2: SUBSTRATE SHEET
3: SEALING LAYER
4: RELEASE FILM
5: ELEMENT SUBSTRATE
6: ORGANIC EL ELEMENT
61: ANODE
62: ORGANIC LAYER
63: CATHODE
7: BARRIER-LIKE THIN FILM LAYER
8: TRANSPARENT RESIN LAYER FOR ORGANIC EL ELEMENT ENCAPSULATION
9: SEALING SUBSTRATE
11: ORGANIC EL DISPLAY

1. A resin composition for element encapsulation for organic electronic devices, the resin composition comprising:
a polyisobutylene resin (A) containing a polyisobutylene skeleton in a main chain or in a side chain and having a weight average molecular weight (Mw) of 300,000 or more; and a tackifying agent (B) as main components,
comprising an organometallic compound (C) having hygroscopic properties, and
having a water content of 1000 ppm or less.

2. The resin composition for element encapsulation for organic electronic devices according to claim 1, wherein the moisture permeability of the resin composition is less than 100 μm·g/m²·day.

3. The resin composition for element encapsulation for organic electronic devices according to claim 1, wherein the tackifying agent (B) is included at a proportion of 10% to 80% by mass relative to the total amount.

4. The resin composition for element encapsulation for organic electronic devices according to claim 1, wherein the tackifying agent (B) is one kind or two or more kinds of hydrogenated resins selected from the group consisting of a hydride of a petroleum resin, hydrogenated rosin, and a hydrogenated terpene resin.

5. The resin composition for element encapsulation for organic electronic devices according to claim 1, wherein the amount of extrusion, which is the difference between the maximum length of one edge in a state of being encapsulated between two sheets of glass plates, and the maximum length of one edge after being left to stand for 150 hours in a state of being encapsulated between two sheets of glass plates under the conditions of a temperature of 85° C. and a relative humidity of 85%, is less than 2 mm.

6. The resin composition for element encapsulation for organic electronic devices according to claim 1, wherein the organometallic compound (C) is incorporated such that the content of the metal is 0.05% to 2.0% by mass relative to the total amount.

7. The resin composition for element encapsulation for organic electronic devices according to claim 1, wherein the organometallic compound (C) is represented by the following formula (1): 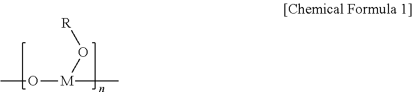
wherein R represents a hydrogen atom, or any one of organic functional groups having 8 or fewer carbon atoms which may have a substituent including an alkyl group, an aryl group, an alkenyl group, an alkoxy group, a cycloalkyl group, a heterocyclic group, and an acyl group; M represents a divalent to tetravalent metal atom; n represents the degree of polymerization and is an integer of 1 or more; and R's may be respectively identical organic functional groups or may be different organic functional groups.

8. The resin composition for element encapsulation for organic electronic devices according to claim 1, wherein the organometallic compound (C) is an organometal having a ligand selected from the group consisting of an alcohol, a diketone, a β-keto ester, and an ether.

9. The resin composition for element encapsulation for organic electronic devices according to claim 1, wherein the light transmittance in the wavelength region of 550 nm is 85% or higher.

10. A resin sheet for element encapsulation for organic electronic devices, the resin sheet comprising at least a sealing layer formed from the resin composition for element encapsulation for organic electronic devices according to claim 1.

11. The resin sheet for element encapsulation for organic electronic devices according to claim 10, wherein a sealing substrate for encapsulating the element for organic electronic devices together with the sealing layer is provided on the surface of the sealing layer opposite to the surface that is pasted to the element for organic electronic devices.

12. The resin sheet for element encapsulation for organic electronic devices according to claim 10, wherein the thickness of the sealing layer is 1 to 50 μm.

13. An organic electroluminescent element, being encapsulated with the resin composition for element encapsulation for organic electronic devices according to claim 1.

14. An organic electroluminescent element, being encapsulated using the sealing layer of the resin sheet for element encapsulation for organic electronic devices according to claim 10.

15. An image display device comprising the organic electroluminescent element according to claim 14.
